(19) United States
(12) Patent Application Publication
(10) Pub. No.: US 2025/0176399 A1
(43) Pub. Date: May 29, 2025

(54) DISPLAY DEVICE

(71) Applicant: SAMSUNG DISPLAY CO., LTD., YONGIN-Si (KR)

(72) Inventor: Jae Hoon KIM, Yongin-si (KR)

(21) Appl. No.: 18/672,765

(22) Filed: May 23, 2024

(30) Foreign Application Priority Data
Nov. 27, 2023 (KR) 10-2023-0166661

(51) Int. Cl. H10K 59/00; H10K 50/115; H10K 59/80

(52) U.S. Cl. CPC H10K 59/771; H10K 59/873; H10K 50/115

(57) ABSTRACT

A display device includes a substrate. A pixel electrode is disposed on the substrate. A bank layer covers lateral edges of the pixel electrode and includes openings defining a plurality of emission areas. A plurality of light-emitting structures is disposed on the pixel electrode. The plurality of light-emitting structures is disposed in the plurality of emission areas, respectively. A common electrode is disposed on the plurality of light-emitting structures and the bank layer. An organic functional layer is disposed on the common electrode and is disposed in the plurality of emission areas. The organic functional layer comprises polyacrylic acid.

This application claims priority under 35 U.S.C. § 119 to Korean Patent Application No. 10-2023-0166661, filed on Nov. 27, 2023 in the Korean Intellectual Property Office, the disclosure of which is incorporated by reference in its entirety herein.

### 1. TECHNICAL FIELD

The present disclosure relates to a display device.

### 2. DISCUSSION OF RELATED ART

As the information-oriented society evolves, demands for display devices are increasing. For example, display devices are being applied to a large variety of electronic devices, including smart phones, digital cameras, laptop computers, navigation devices, and smart televisions.

Display devices include flat panel display devices, such as a liquid-crystal display device, a field emission display device, and a light-emitting display device. Light-emitting display devices may include an organic light-emitting display device including organic light-emitting elements, and an inorganic light-emitting display device including inorganic light-emitting elements, such as quantum dots.

Among these, display devices including quantum dots are under development. Research is being performed to increase the efficiency of display devices using quantum dots.

### SUMMARY

Aspects of the present disclosure provide a display device that can increase the efficiency.

It should be noted that objects of embodiments of the present disclosure are not limited to the above-mentioned object; and other objects of embodiments of the present disclosure will be apparent to those skilled in the art from the following descriptions.

According to an embodiment of the present disclosure, a display device includes a substrate. A pixel electrode is disposed on the substrate. A bank layer covers lateral edges of the pixel electrode and includes openings defining a plurality of emission areas. A plurality of light-emitting structures is disposed on the pixel electrode. The plurality of light-emitting structures is disposed in the plurality of emission areas, respectively. A common electrode is disposed on the plurality of light-emitting structures and the bank layer. An organic functional layer is disposed on the common electrode and is disposed in the plurality of emission areas. The organic functional layer comprises polyacrylic acid.

In an embodiment, the organic functional layer further comprises an acidic substance.

In an embodiment, the acidic substance comprises a carboxyl group.

In an embodiment, the acidic substance comprises citric acid or sulfuric acid.

In an embodiment, the plurality of emission areas comprise a first emission area, a second emission area and a third emission area. The organic functional layer comprises a first functional layer disposed in the first emission area, a second functional layer disposed in the second emission area, and a third functional layer disposed in the third emission area.

In an embodiment, the first functional layer, the second functional layer and the third functional layer have different thicknesses from each other.

In an embodiment, a thickness of the first functional layer is less than a thickness of the second functional layer. The thickness of the second functional layer is less than a thickness of the third functional layer.

In an embodiment, a thickness of the first functional layer is equal to a thickness of the second functional layer. A thickness of the third functional layer is greater than the thickness of the first functional layer and the thickness of the second functional layer.

In an embodiment, the first functional layer, the second functional layer and the third functional layer have a same thickness as each other.

In an embodiment, a thickness of each of the first functional layer, the second functional layer and the third functional layer is in a range of about 100 nm to about 1,400 nm.

In an embodiment, the organic functional layer directly contacts an upper surface of the common electrode.

In an embodiment, the display device further comprises a thin-film encapsulation layer disposed on the organic functional layer. The thin-film encapsulation layer comprises a first inorganic encapsulation film, an organic encapsulation film disposed on the first inorganic encapsulation film, and a second inorganic encapsulation film disposed on the organic encapsulation film.

In an embodiment, each of the light-emitting structures comprises a quantum-dot light-emitting layer and an electron transport layer disposed on the quantum-dot light-emitting layer.

In an embodiment, the electron transport layer comprises metal oxide.

According to an embodiment of the present disclosure, a display device comprises a substrate. A light-emitting element layer is disposed on the substrate and comprising a quantum-dot light-emitting layer and an electron transport layer. A thin-film encapsulation layer is disposed on the light-emitting element layer. An organic functional layer is disposed between the light-emitting element layer and the thin-film encapsulation layer. The organic functional layer comprises polyacrylic acid and an acidic substance.

In an embodiment, the light-emitting element layer comprises a pixel electrode disposed under the quantum-dot light-emitting layer, and a common electrode disposed on the electron transport layer. The organic functional layer directly contacts the common electrode.

In an embodiment, the light-emitting element layer comprises a bank layer that covers lateral edges of the pixel electrode and includes openings defining a plurality of emission areas. The plurality of emission areas comprise a first emission area, a second emission area and a third emission area. The organic functional layer comprises a first functional layer disposed in the first emission area, a second functional layer disposed in the second emission area, and a third functional layer disposed in the third emission area.

In an embodiment, a thickness of the first functional layer is less than a thickness of the second functional layer, and the thickness of the second functional layer is less than a thickness of the third functional layer.

In an embodiment, the first emission area emits first light. The first light is red. The second emission area emits second light. The second light is green. The third emission area emits third light. The third light is blue.

In an embodiment, a thickness of the first functional layer is equal to a thickness of the second functional layer, and a thickness of the third functional layer is greater than the thickness of the first functional layer and the thickness of the second functional layer.

According to an embodiment of the present disclosure, by forming an organic functional layer containing polyacrylic acid on a light-emitting element layer, the current characteristics of an electron transport layer can be increased, so that the efficiency of the display device can be increased.

It should be noted that effects of embodiments of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a perspective view showing a display device according to an embodiment of the present disclosure.

FIG. 2 is a plan view showing a display device according to an embodiment of the present disclosure.

FIG. 3 is a cross-sectional view taken along line Q1-Q1′ of FIG. 2 according to an embodiment of the present disclosure.

FIG. 4 is an enlarged plan view of area A of FIG. 2 according to an embodiment of the present disclosure.

FIG. 5 is a cross-sectional view taken along line Q2-Q2′ of FIG. 4 according to an embodiment of the present disclosure.

FIG. 6 is an enlarged cross-sectional view of the first emission area in the display device shown in FIG. 5 according to an embodiment of the present disclosure.

FIG. 7 is a view schematically showing the first to third emission areas shown in FIG. 5 according to an embodiment of the present disclosure.

FIG. 8 is a schematic view of molecules for illustrating a role of an organic functional layer according to an embodiment of the present disclosure.

FIG. 9 is a graph showing trap density versus temperature of light-emitting elements according to an embodiment of the present disclosure.

FIG. 10 is a graph showing the efficiency of the first light-emitting element according to an embodiment of the present disclosure.

FIG. 11 is a graph showing the efficiency of the second light-emitting element according to an embodiment of the present disclosure.

FIG. 12 is a graph showing the efficiency of the third light-emitting element according to an embodiment of the present disclosure.

FIG. 13 is a cross-sectional view showing a display device according to an embodiment of the present disclosure.

FIG. 14 is a cross-sectional view showing a display device according to an embodiment of the present disclosure.

### DETAILED DESCRIPTION OF EMBODIMENTS

The present disclosure will now be described more fully hereinafter with reference to the accompanying drawings, in which non-limiting embodiments of the present disclosure are shown. The present disclosure may, however, be embodied in different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

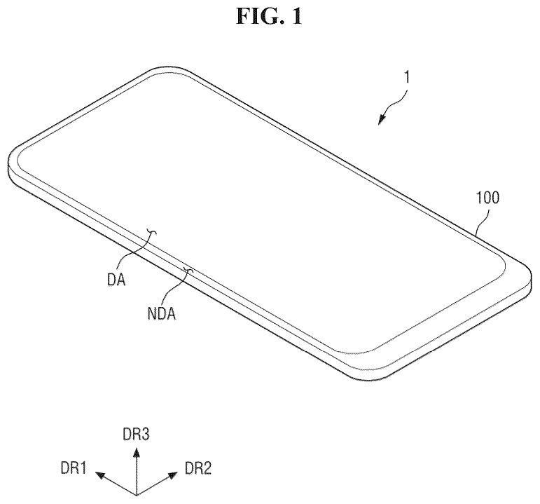

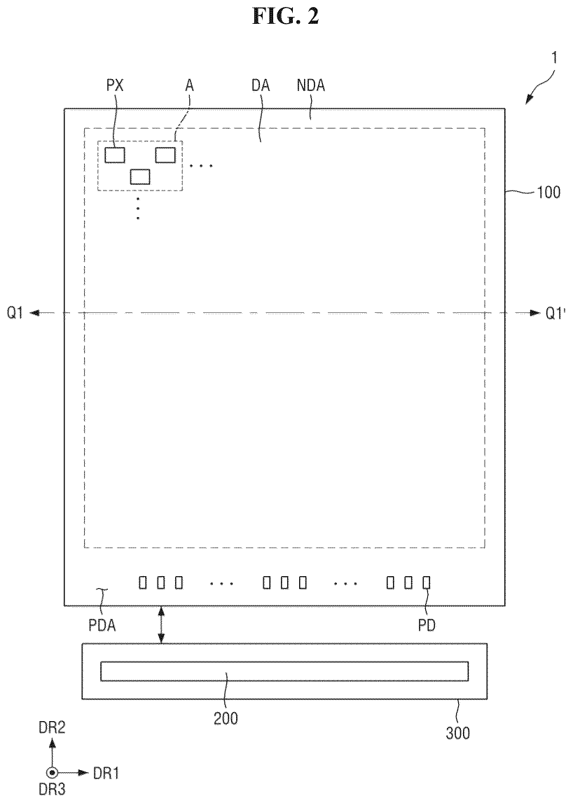

FIG. 1 is a perspective view showing a display device according to an embodiment of the present disclosure. FIG. 2 is a plan view showing a display device according to an embodiment of the present disclosure.

Referring to FIG. 1, the display device 1 may display at least one moving image and/or at least one still image. A display device 1 may refer to any electronic device that provides a display screen to generate images to a viewer. For example, in an embodiment the display device 1 may include a television, a laptop computer, a monitor, an electronic billboard, an Internet of Things device, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

Examples of the display device 1 may include an inorganic light-emitting diode display device, an organic light-emitting display device, a quantum-dot light-emitting display device, a plasma display device, a field emission display device, etc. In the following description, an inorganic light-emitting diode display device is employed as an example of the display device. However, embodiments of the present disclosure are not necessarily limited thereto. For example, any other display device may be employed as long as the technical idea of the present disclosure can be equally applied.

The shape of the display device 1 may be modified in a variety of ways. For example, in an embodiment the display device 1 may have shapes such as a rectangle with longer lateral sides, a rectangle with longer vertical sides, a square, a quadrangle with rounded corners (vertices), other polygons, a circle, etc. The shape of a display area DA of the display device 1 may also be similar to the overall shape of the display device 1. In the example shown in FIG. 1, the display device 1 has a rectangular shape with the longer sides in the second direction Y. However, embodiments of the present disclosure are not necessarily limited thereto.

Referring to FIGS. 1 and 2, the display device 1 may include a display panel 100, a display driver 200 and a circuit board 300.

In an embodiment, the display panel 100 may be formed in a rectangular plane having relatively short sides in the first direction DR1 and relatively long sides in the second direction DR2 intersecting the first direction DR1. Each of the corners where the relatively short side in the first direction DR1 meets the relatively long side in the second direction DR2 may be rounded with a predetermined curvature or may be a right angle. The shape of the display panel 100 when viewed from the top (e.g., in a plane defined in the first and second directions DR1, DR2) is not necessarily limited to a quadrangular shape, but may be formed in a different polygonal shape, a circular shape, or an elliptical shape. The display panel 100 may be, but is not necessarily limited to being, formed to be flat. In some embodiments, the display panel 10 may include curved portions formed at left and right ends thereof and having a constant or varying curvature. In addition, the display panel 100 may be flexible so that it can be curved, bent, folded or rolled.

The display panel 100 may include a display area DA, a non-display area NDA and a pad area PDA.

In an embodiment, the display area DA may be generally positioned in the center of the display device 1 (e.g., in the first and second directions DR1, DR2). A plurality of pixels PX may be disposed in the display area DA. Each of the plurality of pixels PX may be defined as the minimum unit that outputs light. A plurality of pixels PX may be connected to signal lines located in the non-display area NDA. The display area DA may emit light from emission areas or openings included in the plurality of pixels PX.

The non-display area NDA may be located on the outer side of the display area DA (e.g., in the first and/or second directions DR1, DR2). The non-display area NDA may be located on the outer side of the border of the display panel 100 to surround the display area DA. In an embodiment, the non-display area NDA may include a gate driver that supplies gate signals to gate lines, and fan-out lines that connect the display driver 200 with the display area DA.

The display driver 200 may output signals and voltages for driving the display panel 100. For example, the display driver 200 may output signals and voltages for driving the pixels PX disposed in the display area DA. The display driver 200 may supply data voltages to data lines of the display panel 100. The display driver 200 may provide supply voltages to voltage lines and may provide gate control signals to the gate driver of the display panel 100.

In an embodiment, the circuit board 300 may be attached on the pad area of the display panel 100 using an anisotropic conductive film (ACF). Lead lines of the circuit board 300 may be electrically connected to the pads of the display panel 300. In an embodiment, the circuit board 300 may be a flexible printed circuit board (FPCB), a printed circuit board (PCB), or a flexible film such as a chip-on-film (COF).

In an embodiment, the display driver 200 may be implemented as an integrated circuit (IC) and may be attached on the display panel 100 by a chip-on-glass (COG) technique, a chip-on-plastic (COP) technique, or ultrasonic bonding.

A plurality of display pads PD may be disposed in the pad area PDA of the display panel 100. A plurality of display pads PD may be disposed at an edge of the pad area PDA. The plurality of display pads DP may be connected to a graphic system through the circuit board 300. The plurality of display pads DP may be connected to the circuit board 300 to receive digital video data and may supply the digital video data to the display driver 200.

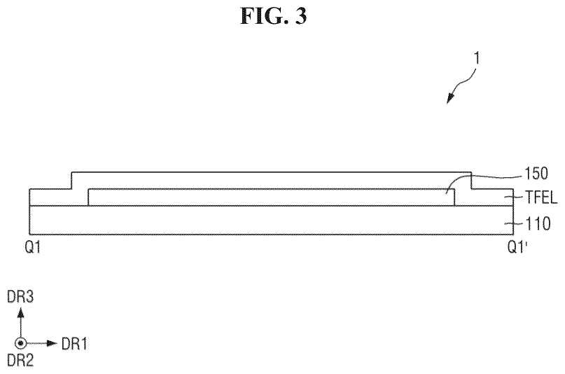

FIG. 3 is a cross-sectional view taken along line Q1-Q1′ of FIG. 2.

Referring to FIG. 3, the display device 1 may include a substrate 110, a light-emitting element layer 150, and a thin-film encapsulation layer TFEL.

The substrate 110 may be a base substrate or a base member. In an embodiment, the substrate 110 may be a flexible substrate that can be bent, folded, or rolled. For example, the substrate 110 that is flexible may include, but is not necessarily limited to, a polymer resin such as polyimide PI. In an embodiment, the substrate 110 may include a glass material or a metal material.

The light-emitting element layer 150 may include pixel circuits including switching elements, a pixel-defining layer that defines the emission areas or open areas, and self-light-emitting elements. For example, the self-light-emitting element may include, but is not necessarily limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The thin-film encapsulation layer TFEL can prevent impurities such as moisture and air from penetrating from the outside (e.g., the external environment) and diffusing into the light-emitting element layer 150. In an embodiment, the thin-film encapsulation layer TFEL may have a structure in which inorganic layers and organic layers are stacked (e.g., alternately stacked in the third direction DR3).

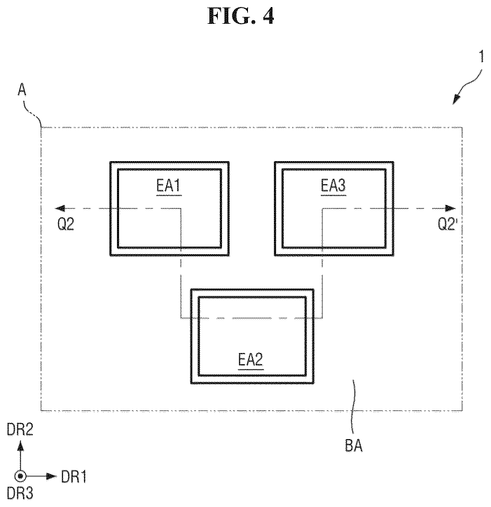

FIG. 4 is an enlarged plan view of area A of FIG. 2.

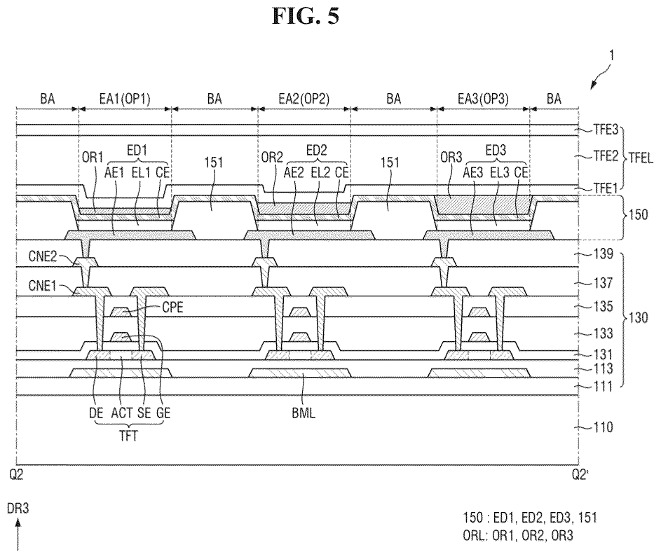

Referring to FIG. 4, the display device 1 may include a plurality of emission areas EA1, EA2 and EA3 arranged in the display area DA. In an embodiment, the emission areas EA1, EA2 and EA3 may include first emission areas EA1, second emission areas EA2 and third emission areas EA3 that emit lights of different colors. Each of the emission areas EA1, EA2 and EA3 may emit red, green or blue light. The colors of lights emitted from the emission areas EA1, EA2 and EA3 may be determined based on the type of light-emitting elements ED1, ED2 and ED3 disposed in the light-emitting element layer 150 (see FIG. 5) in the emission areas EA1, EA2 and EA3. According to an embodiment of the present disclosure, the first emission areas EA1 may emit first light of red color, the second emission areas EA2 may emit second light of green color, and the third emission areas EA3 may emit third light of blue color. However, embodiments of the present disclosure are not necessarily limited thereto and the number of emission areas and the lights that are emitted thereby may vary.

In an embodiment, a non-emission area BA may surround each of the emission areas EA1, EA2 and EA3 (e.g., in the first and second directions DR1, DR2). The non-emission area BA may not transmit light. However, embodiments of the present disclosure are not necessarily limited thereto.

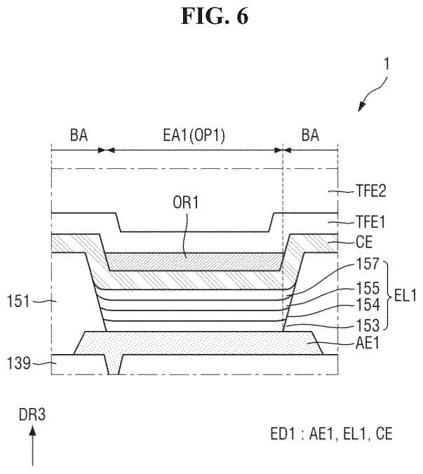

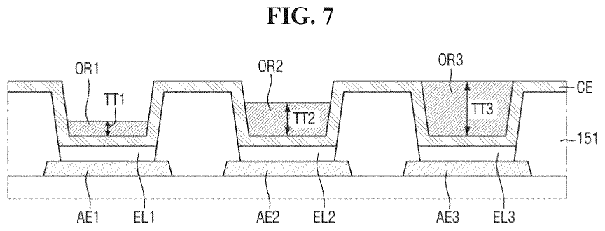

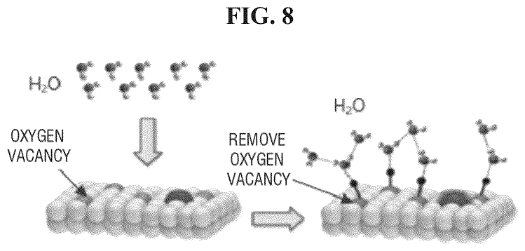

FIG. 5 is a cross-sectional view taken along line Q2-Q2′ of FIG. 4. FIG. 6 is an enlarged cross-sectional view of the first emission area in the display device shown in FIG. 5. FIG. 7 is a view schematically showing the first to third emission areas shown in FIG. 5. FIG. 8 is a schematic view of molecules for illustrating a role of an organic functional layer according to an embodiment.

Referring to FIG. 5, in an embodiment the display device 1 may include a substrate 110, a thin-film transistor layer 130, a light-emitting element layer 150, an organic functional layer ORL, and a thin-film encapsulation layer TFEL.

The thin-film transistor layer 130 may be disposed on the substrate 110 (e.g., disposed directly thereon in the third direction DR3). In an embodiment, the thin-film transistor layer 130 may include a first buffer layer 111, a bottom metal layer BML, a second buffer layer 113, a thin-film transistor TFT, a gate insulator 131, a first interlayer dielectric layer 133, a capacitor electrode CPE, a second interlayer dielectric layer 135, a first connection electrode CNE1, a first passivation layer 137, a second connection electrode CNE2 and a second passivation layer 139.

The first buffer layer 111 may be disposed on the substrate 110 (e.g., disposed directly thereon in the third direction DR3). The first buffer layer 111 may include an inorganic film capable of preventing permeation of air or moisture. For example, in an embodiment the first buffer layer 111 may include a plurality of inorganic films stacked on one another alternately (e.g., in the third direction DR3).

The bottom metal layer BML may be disposed on the first buffer layer 111 (e.g., disposed directly thereon in the third direction DR3). For example, in an embodiment the bottom metal layer BML may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second buffer layer 113 may cover the first buffer layer 111 and the bottom metal layer BML. The second buffer layer 113 may include an inorganic film capable of preventing permeation of air or moisture. For example, in an embodiment the second buffer layer 113 may include a plurality of inorganic films stacked on one another alternately (e.g., in the third direction DR3).

The thin-film transistor TFT may be disposed on the second buffer layer 113 (e.g., disposed directly thereon in the third direction DR3) and may form a pixel circuit of each of a plurality of pixels. The thin-film transistor TFT may be a driving transistor or a switching transistor of the pixel circuit. The thin-film transistor TFT may include a semiconductor layer ACT, a source electrode SE, a drain electrode DE and a gate electrode GE. In an embodiment, the thin-film transistor TFT may include not only an oxide thin-film transistor (oxide TFT) but also a low-temperature polysilicon thin-film transistor (LTPS).

The semiconductor layer ACT may be disposed on the second buffer layer 113 (e.g., disposed directly thereon in the third direction DR3). The semiconductor layer ACT may overlap the bottom metal layer BML and the gate electrode GE in the thickness direction (e.g., in the third direction DR3) and may be insulated from the gate electrode GE by the gate insulator 131. The material of a portion of the semiconductor layer ACT may be made conductive to form the source electrode SE and the drain electrode DE.

The gate electrode GE may be disposed on the gate insulator 131 (e.g., disposed directly thereon in the third direction DR3). The gate electrode GE may overlap the semiconductor layer ACT with the gate insulator 131 interposed therebetween (e.g., in the third direction DR3).

The gate insulator 131 may be disposed on the semiconductor layer ACT (e.g., disposed directly thereon in the third direction DR3). For example, the gate insulator 131 may cover the semiconductor layer ACT and the second buffer layer 113, and may insulate the semiconductor layer ACT from the gate electrode GE. The gate insulator 131 may include a contact hole through which the first connection electrode CNE1 passes.

The first interlayer dielectric layer 133 may cover the gate electrode GE and the gate insulator 131. In an embodiment, the first interlayer dielectric layer 133 may include a contact hole through which the first connection electrode CNE1 passes. The contact hole of the first interlayer dielectric layer 133 may be connected to the contact hole of the gate insulating layer 131 and a contact hole of the second interlayer dielectric layer 135.

The capacitor electrode CPE may be disposed on the first interlayer dielectric layer 133 (e.g., disposed directly thereon in the third direction DR3). The capacitor electrode CPE may overlap with the gate electrode GE in the thickness direction (e.g., in the third direction DR3). The capacitor electrode CPE and the gate electrode GE may form a capacitance.

The second interlayer dielectric layer 135 may cover the capacitor electrode CPE and the first interlayer dielectric layer 133. In an embodiment, the second interlayer dielectric layer 135 may include a contact hole through which the first connection electrode CNE1 passes. The contact hole of the second interlayer dielectric layer 135 may be connected to the contact hole of the first interlayer dielectric layer 133 and the contact hole of the gate insulating layer 131.

The first connection electrode CNE1 may be disposed on the second interlayer dielectric layer 135 (e.g., disposed directly thereon in the third direction DR3). The first connection electrode CNE1 may electrically connect the drain electrode DE of the thin-film transistor TFT with the second connection electrode CNE2. In an embodiment, the first connection electrode CNE1 may be in direct contact with the drain electrode DE of the thin-film transistor TFT through a contact hole formed in the second interlayer dielectric layer 135, the first interlayer dielectric layer 133 and the gate insulator 131.

The first passivation layer 137 may cover the first connection electrode CNE1 and the second interlayer dielectric layer 135. The first passivation layer 137 can protect the thin-film transistor TFT. The first passivation layer 137 may include a contact hole through which the second connection electrode CNE2 passes.

The second connection electrode CNE2 may be disposed on the first protective layer 137 (e.g., disposed directly thereon in the third direction DR3). The second connection electrode CNE2 may electrically connect the first connection electrode CNE1 with the first to third pixel electrodes AE1, AE2 and AE3 of the light-emitting elements ED1, ED2 and ED3. The second connection electrode CNE2 may be in direct contact with the first connection electrode CNE1 through a contact hole formed in the first passivation layer 137.

The second passivation layer 139 may cover the second connection electrode CNE2 and the first passivation layer 137. The second passivation layer 139 may include contact holes through which the first to third pixel electrodes AE1, AE2 and ARE3 of the light-emitting elements ED1, ED2 and ED3 pass.

The light-emitting element layer 150 may be disposed on the thin-film transistor layer 130 (e.g., disposed directly thereon in the third direction DR3). In an embodiment, the light-emitting element layer 150 includes a bank layer 151 defining a plurality of emission areas EA1, EA2 and EA3, and a plurality of light-emitting elements ED1, ED2, ED3 disposed in the plurality of emission areas EA1, EA2 and EA3, respectively. The light-emitting elements ED1, ED2 and ED3 may include the first to third pixel electrodes AE1, AE2 and AE3, first to third light-emitting structures EL1, EL2 and EL3, and a common electrode, respectively.

The first to third emission areas EA1, EA2 and EA3 defined by the bank layer 151 may be defined by a plurality of first to third openings OP1, OP2 and OP3 formed by the bank layer 151.

In an embodiment, the light-emitting elements may include a first light-emitting element ED1 disposed in the first emission area EA1, a second light-emitting element ED2 disposed in the second emission area EA2, and a third light-emitting element ED3 disposed in the third emission area EA3. The first to third light-emitting elements ED1, ED2 and ED3 may emit lights of different colors from each other, such as red, blue, green and white, depending on the materials of the first to third light-emitting structures EL1, EL2 and EL3. For example, the first light-emitting element ED1 disposed in the first emission area EA1 may emit red light of the first color, the second light-emitting element ED2 disposed in the second emission area EA2 may emit green light of the second color, and the third light-emitting element ED3 disposed in the third emission area EA3 may emit blue light of the third color. In an embodiment, the first to third emission areas EA1, EA2 and EA3 forming a single pixel may include the first to third light-emitting elements ED1, ED2 and ED3 emitting lights of different colors to represent black-and-white or grayscale images.

The first to third pixel electrodes AE1, AE2 and AE3 may be formed on the second passivation layer 139 (e.g., disposed directly thereon in the third direction DR3). The first to third pixel electrodes AE1, AE2 and AE3 may be disposed in the emission areas EA1, EA2 and EA3, respectively. The first to third pixel electrodes AE1, AE2 and AE3 may be electrically connected to the drain electrode DE of the thin-film transistor TFT through the first and second connection electrodes CNE1 and CNE2. In an embodiment, the pixel electrodes may include a first pixel electrode PE1 disposed in the first emission area EA1, the second pixel electrode PE2 disposed in the second emission area EA2, and the third pixel electrode PE3 disposed in the third emission area EA3. The first pixel electrode AE1, the second pixel electrode AE2 and the third pixel electrode AE3 may be spaced apart from one another on the second passivation layer 139.

In an embodiment, the first to third pixel electrodes AE1, AE2 and AE3 may include indium-tin-oxide (ITO), indium-zinc-oxide (IZO), zinc oxide (ZnO) and indium oxide (In₂O₃) and may include a material that is transparent and has a high work function. In an embodiment in which the first to third pixel electrodes AE1, AE2 and AE3 are reflective electrodes, the pixel electrodes AE1, AE2 and AE3 may have a stack structure in which the above-described material layer having a high work function, and a reflective material such as silver (Ag), magnesium (Mg), aluminum (Al), platinum (Pt), lead (Pb), gold (Au), nickel (Ni), neodymium (Nd), iridium (Ir), chrome (Cr), lithium (Li), calcium (Ca) or a mixture thereof and stacked. For example, in an embodiment, the first to third pixel electrodes AE1, AE2 and AE3 may have, but is not necessarily limited to, a multilayer structure of ITO/Mg, ITO/MgF, ITO/Ag, and ITO/Ag/ITO.

The display device 1 may include the bank layer 151 disposed over the second passivation layer 139 and the first to third pixel electrodes AE1, AE2, and AE3. In an embodiment, the bank layer 151 covers an edge (e.g., lateral edges) of each of the first to third pixel electrodes AE1, AE2, and AE3 and exposes a portion of the first to third pixel electrodes, AE1, AE2, and AE3, such as a central portion thereof. The bank layer 151 forms the plurality of openings OP1, OP2 and OP3 that define first to third light emitting areas EA1, EA2 and EA3. The bank layer 151 may be formed entirely on the second passivation layer 139, and portions of the upper surfaces of the first to third pixel electrodes AE1, AE2 and AE3 are exposed by the respective openings OP1, OP2 and OP3.

In an embodiment, the bank layer 151 may include an organic material. Examples of the organic material may include polyacrylate resin, epoxy resin, phenolic resin, polyamide resin, polyimide resin, unsaturated polyesters resin, polyphenylene ether resin, polyphenylene sulfide resin, benzocyclobutene (BCB), etc.

The first to third light-emitting structures EL1, EL2 and EL3 may be disposed on the first to third pixel electrodes AE1, AE2 and AE3, respectively. The first to third light-emitting structures EL1, EL2 and EL3 of the light-emitting elements ED1, ED2 and ED3 may emit light as the thin-film transistor TFT applies predetermined voltages to the first to third pixel electrodes AE1, AE2 and AE3 of the light-emitting elements ED1, ED2 and ED3, and the common electrode CE of the light-emitting elements ED1, ED2 and ED3 receives a common voltage or cathode voltage.

In an embodiment, the light-emitting structures may include a first light-emitting structure EL1, a second light-emitting structure EL2, and a third light-emitting structure EL3 disposed in different emission areas EA1, EA2 and EA3. The first light-emitting structure EL1 may be disposed on the first pixel electrode AE1 (e.g., in the third direction DR3) in the first emission area EA1, the second light-emitting structure EL2 may be disposed on the second pixel electrode AE2 (e.g., in the third direction DR3) in the second emission area EA2, and the third light-emitting structure EL3 may be disposed on the third pixel electrode AE3 (e.g., in the third direction DR3) in the third emission area EA3. In an embodiment, the first to third light-emitting structures EL1, EL2 and EL3 included in the display device 1 may include quantum dots.

FIG. 6 illustrates an example of the first emission area EA1. The first light-emitting structure EL1 will be described as an example of the first to third light-emitting structures EL1, EL2 and EL3.

In an embodiment, the first light-emitting structure EL1 may include a hole injection layer 153, a hole transport layer 154, a quantum-dot light-emitting layer 155, and an electron transport layer 157.

In an embodiment, the hole injection layer 153 may be disposed on the first to third pixel electrodes AE1, AE2 and AE3 (e.g., disposed directly thereon in the third direction DR3). The hole injection layer 153 may facilitate injection of holes from the first to third pixel electrodes AE1, AE2 and AE3 into the quantum-dot light-emitting layer 155.

For example, in an embodiment the hole injection layer 153 may include phthalocyanine compounds such as copper phthalocyanine, DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino] triphenylamine), TDATA (4,4′4″-Tris(N,Ndiphenylamino)triphenylamine), 2-TNATA (4,4′,4″-tris {N,-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/camphor sulfonic acid), PANI/PSS (polyaniline/poly(4-styrenesulfonate)), NPD (N,N′-di(naphthalene-1-yl)-N,N′-diphenylbenzidine), polyetherketone containing triphenylamine (TPAPEK), 4-Isopropyl-4′-methyldiphenyliodonium[tetrakis(pentafluorophenyl) borate], HAT-CN (dipyrazino[2,3-f:2′,3′-h] quinoxaline-2,3,6,7,10,11-hexacarbonitrile), etc.

The hole transport layer 154 may be disposed on the hole injection layer 153 (e.g., disposed directly thereon in the third direction DR3). The hole transport layer 154 may facilitate transport of holes from the first to third pixel electrodes AE1, AE2 and AE3 into the quantum-dot light-emitting layer 155. For example, in an embodiment the hole transport layer 154 may include carbazole derivatives such as N-phenylcarbazole and polyvinylcarbazole, fluorene derivatives, TPD (N,N′-bis(3-methylphenyl)-N,N′-diphenyl-[1,1-biphenyl]-4,4′-diamine), triphenylamine derivatives such as TCTA (4,4′,4″-tris(N-carbazolyl)triphenylamine), NPD (N,N′-di(naphthalene-1-yl)-N,N′-diphenyl-benzidine), TAPC (4,4′-Cyclohexylidene bis[N,Nbis(4-methylphenyl)benzenamine]), HMTPD (4,4′-Bis[N,N′-(3-tolyl)amino]-3,3′-dimethylbiphenyl), mCP(1,3-Bis(N-carbazolyl)benzene), etc.

The quantum-dot light-emitting layer 155 may be disposed on the hole transport layer 154 (e.g., disposed directly thereon in the third direction DR3). The quantum-dot light-emitting layer 155 may include a plurality of quantum dots.

Quantum dots can control the color of light they emit depending on the particle size, and accordingly, quantum dots can emit lights of a variety of colors such as blue, red, and green. As the particle size of the quantum dots decreases, lights in a shorter wavelength range may be emitted. For example, in quantum dots having the same core, the particle size of quantum dots that emit green light may be less than the particle size of quantum dots that emit red light. In addition, in quantum dots having the same core, the particle size of quantum dots that emit blue light may be less than the particle size of quantum dots that emit green light. It should be understood, however, that embodiments of the present disclosure are not necessarily limited thereto. Even in quantum dots having the same core, the particle size may be adjusted depending on the material for the shell and the thickness of the shell. For example, when quantum dots emit lights of a variety of colors such as blue, red and green, quantum dots with different colors may have different core materials.

In an embodiment, the quantum dots may have a spherical shape, a pyramidal shape and a multi-arm shape, or may be cubic nanoparticles, nanotubes, nanowires, nanofibers, nano-platelets or the like.

In an embodiment, the quantum-dot light-emitting layer 155 may include a core layer containing quantum-dot particles and a shell layer surrounding the core layer. Quantum-dot particles may form a ligand bond with inorganic particles on the surface of the shell layer and around it. In an embodiment, a hydrothermal treatment process may be further performed on the display panel 100 in which the quantum-dot light-emitting layer 155 is formed to prevent the quantum-dot particles from forming a ligand bond with the inorganic particles. In an embodiment, the hydrothermal treatment process of the quantum-dot light-emitting layer 155 may be performed through a low-temperature annealing process of 100° C. or lower using steam, unlike a high-temperature annealing process of 150° C. or higher. It is possible to prevent the quantum-dot particles in the quantum-dot light-emitting layer 155 from forming ligand bond with the inorganic particles during the hydrothermal treatment process of the quantum-dot light-emitting layer 155.

Although a hydrothermal treatment process is performed on the quantum-dot light-emitting layer 155 after the quantum-dot light-emitting layer 155 containing quantum-dot particles has been formed according to an embodiment of the present disclosure, embodiments of the present disclosure are not necessarily limited thereto.

The hydrothermal treatment process according to an embodiment of the present disclosure may be performed to form at least one layer containing nanoparticles among the hole injection layer 153, the hole transport layer 154 and the electron transport layer 157 as well as the quantum-dot light-emitting layer 155. For example, in an embodiment, the hydrothermal treatment process may be performed at 100° C. or lower using water vapor at least once to form at least one layer among the hole injection layer 153, the hole transport layer 154, the quantum-dot light-emitting layer 155 and the electron transport layer 157.

In an embodiment, the core layer of the quantum-dot light-emitting layer 155 may be selected from group II-VI compounds, group III-V compounds, group IV-VI compounds, group IV elements, group IV compounds, and a combination thereof.

In an embodiment, the group II-VI compounds may be selected from the group consisting of: binary compounds selected from the group consisting of CdSe, CdTe, ZnS, ZnSe, ZnTe, ZnO, HgS, HgSe, HgTe, MgSe, MgS and a mixture thereof; ternary compounds selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof.

In an embodiment, the group III-V compounds may be selected from the group consisting of: binary compounds selected from the group consisting of GaN, GaP, GaAs, GaSb, AlN, AlP, AlAs, AlSb, InN, InP, InAs, InSb and a mixture thereof; ternary compounds selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and a mixture thereof; and quaternary compounds selected from the group consisting of GaAlNAs, GaAlNSb, GaAlPAs, GaAlPSb, GalnNP, GalnNAs, GalnNSb, GalnPAs, GalnPSb, InGaAlP, InAlNP, InAlNAs, InAlNSb, InAlPAs, InAlPSb and a mixture thereof.

In an embodiment, the group IV-VI compounds may be selected from the group consisting of: binary compounds selected from the group consisting of SnS, SnSe, SnTe, PbS, PbSe, PbTe and a mixture thereof; ternary compounds selected from the group consisting of SnSeS, SnSeTe, SnSTe, PbSeS, PbSeTe, PbSTe, SnPbS, SnPbSe, SnPbTe and a mixture thereof; and quaternary compounds selected from the group consisting of SnPbSSe, SnPbSeTe, SnPbSTe and a mixture thereof.

In an embodiment, the group IV elements may be selected from the group consisting of Si, Ge and a mixture thereof. The group IV compounds may be binary compounds selected from the group consisting of SiC, SiGe and a mixture thereof.

The shell layer may serve as a protective layer for maintaining the semiconductor properties by preventing chemical denaturation of the core layer and/or as a charging layer for imparting electrophoretic properties to the quantum dots. In an embodiment, the shell layer may include an oxide of a metal or a non-metal, a semiconductor compound, a combination thereof, etc. For example, examples of the metal or non-metal oxide may include, but is not necessarily limited to, binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO or ternary compounds such as MgAl₂O₄, CoFe₂O₄, NiFe₂O₄ and CoMn₂O₄. Examples of the semiconductor compound may include, but is not necessarily limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

In an embodiment, the diameter of the core layer of the quantum dots may be, but is not necessarily limited to, in a range of about 1 nm to about 10 nm. In an embodiment, the thickness of the shell layer may be, but is not necessarily limited to, in a range of about 1 nm to about 10 nm. The quantum dots included in the quantum-dot light-emitting layer 155 may be stacked to form layers. For example, in an embodiment, in the quantum-dot light-emitting layer 155, the quantum dots may be aligned adjacent to each other to form one layer, or may be aligned to form multiple layers, such as two or three layers.

The electron transport layer 157 may be disposed on the quantum-dot light-emitting layer 155 (e.g., disposed directly thereon in the third direction DR3). The electron transport layer 157 may facilitate injection and transport of electrons from the common electrode CE to the quantum-dot light-emitting layer 155. The electron transport layer 157 may be formed of a composition for the electron transport layer, and the composition for the electron transport layer may contain inorganic particles. The inorganic particles may include metal oxides. For example, in an embodiment the electron transport layer 157 of the display device 1 may include, but is not necessarily limited to, ZnMgO or ZnO. In addition to this, in an embodiment the electron transport layer 157 may include binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂ and Y₂O₃, or ternary compounds such as ZnMgO, MgAl₂O₄, CoFe₂O₄, NiFe₂O₄, CoMn₂O₄, BaTiO₃, BaZrO₃ and ZrSiO₄.

According to some embodiments, the hole injection layer 153, the hole transport layer 154, the quantum-dot light-emitting layer 155 and the electron transport layer 157 of the first light-emitting structure EL1 may be fabricated via an inkjet printing process.

The common electrode CE may be disposed on the first to third light-emitting structures EL1, EL2 and EL3 (e.g., disposed directly thereon in the third direction DR3). The common electrode CE may cover the first to third light-emitting structures EL1, EL2 and EL3 located in the respective first to third emission area EA1, EA2 and EA3 and the bank layer 151. The common electrode CE may include a transparent conductive material so that light generated in the first to third light-emitting structures EL1, EL2 and EL3 can exit. The common electrode CE may receive a common voltage or a low-level voltage. When the first to third pixel electrodes AE1, AE2 and AE3 receive the voltage equal to the data voltage and the common electrode CE receives the low-level voltage, a potential difference is formed between the first to third pixel electrodes AE1, AE2 and AE3 and the common electrode CE, so that the first to third light-emitting structures EL1, EL2 and EL3 can emit light.

In an embodiment, the common electrode CE may include a material layer having a small work function such as Li, Ca, LiF/Ca, LiF/Al, Al, Mg, Ag, Pt, Pd, Ni, Au, Nd, Ir, Cr, BaF and Ba, or a compound or mixture thereof (e.g., a mixture of Ag and Mg). The common electrode CE may further include a transparent metal oxide layer disposed on the material layer having a small work function.

In an embodiment, the common electrode CE may include a capping layer on a transparent conductive metal layer. The capping layer may protect the transparent conductive metal. For example, the common electrode CE may be a single film containing a conductive metal or a multilayer film containing a conductive metal and a capping layer.

Referring to FIGS. 5 to 8, the display device 1 may include an organic functional layer ORL disposed on the common electrode CE (e.g., disposed directly thereon). The organic functional layer ORL may be disposed between the common electrode CE and the thin-film encapsulation layer TFEL (e.g., in the third direction DR3). In an embodiment, the organic functional layer ORL may include a first functional layer OR1 disposed in the first emission area EA1, a second functional layer OR2 disposed in the second emission area EA2, and a third functional layer OR3 disposed in the third emission area EA3. Each of the first functional layer OR1, the second functional layer OR2 and the third functional layer OR3 may directly contact the upper surface of the common electrode CE.

The organic functional layer ORL may include an organic material. For example, in an embodiment the organic functional layer ORL may include polyacrylic acid (PAA). Polyacrylic acid contains hydrogen, and may release hydrogen ions (H+) through hydrogen ion (H+) polymerization reaction when the organic functional layer ORL is irradiated with UV. The hydrogen used in this embodiment may include both hydrogen ions (H+) and hydrogen molecules (H₂). In addition, polyacrylic acid may release H₂O that it contains. In some embodiments, polyacrylic acid may generate additional HO by heat.

Hydrogen ions and H₂O released from polyacrylic acid may react with metal oxide contained in the first to third light-emitting structures EL1, EL2 and EL3. For example, hydrogen ions and H₂O may diffuse into the electron transport layer 157 disposed below the common electrode CE and react with the electron transport layer 157. For example, as shown in FIG. 8, H₂O forms a Zn—OH₂ bond with Zn of ZnO, a metal oxide, and can remove the oxygen vacancy of the metal oxide by filling it, which otherwise may act as an electron trap.

According to an embodiment of the present disclosure, hydrogen ions and H₂O included in the organic functional layer ORL react with zinc magnesium oxide (ZnMgO) or zinc oxide (ZnO) included in the electron transport layer 157 to remove the oxygen vacancy, thereby increasing the current injection characteristics of the electron transport layer 157.

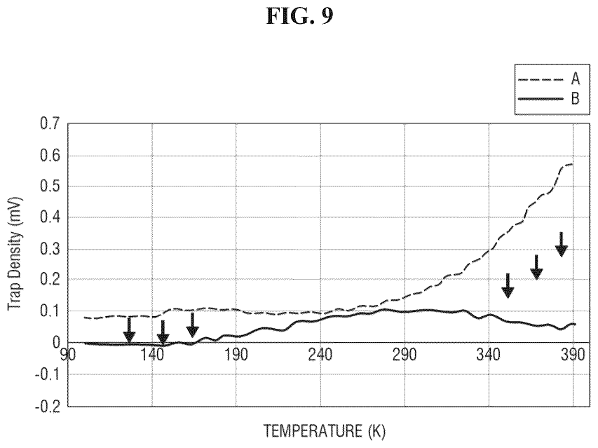

FIG. 9 is a graph showing trap density versus temperature of light-emitting elements. For example, the graph shows the trap density of light-emitting elements with and without an organic functional layer ORL over temperature.

Referring to FIG. 9, the graph shows that the trap density of a light-emitting element (B) including the organic functional layer ORL is significantly reduced compared to the light-emitting element (A) that does not include the organic functional layer ORL.

According to this embodiment, the organic functional layer ORL is included on each of the first to third light-emitting elements ED1, ED2 and ED3 to remove oxygen vacancies in the electron transport layer 157 to reduce the trap density. This shows that the efficiency, such as current efficiency, of each of the first to third light-emitting elements ED1, ED2 and ED3 can be increased.

In addition, in an embodiment the organic functional layer ORL may further include an acidic substance in addition to polyacrylic acid. The acidic substance may contain a carboxyl group (—COOH). For example, in an embodiment the acidic substance may be sulfuric acid or citric acid. The carboxyl group may react with the metal oxide of the electron transport layer 157 to generate H₂O, so that the oxygen vacancies in the metal oxide can be further filled.

According to an embodiment of the present disclosure, the first functional layer OR1, the second functional layer OR2 and the third functional layer OR3 may have different thicknesses (e.g., length in the third direction DR3) from each other. For example, in an embodiment, the thickness TT1 of the first functional layer OR1 may be less than the thickness TT2 of the second functional layer OR2, and the thickness TT2 of the second functional layer OR2 may be less than the thickness TT3 of the third functional layer OR3. For example, the thickness TT3 of the third functional layer OR3 may be greater than the thickness TT2 of the second functional layer OR2, and the thickness TT2 of the second functional layer OR2 may be greater than the thickness TT1 of the first functional layer OR1.

For example, in an embodiment the thickness TT1 of the first functional layer OR1 may be in a range of about 100 nm to about 1,400 nm, the thickness TT2 of the second functional layer OR2 may be in a range of about 100 nm to about 1,400 nm, the thickness TT3 of the third functional layer OR3 may be in a range of about 100 to about 1,400 nm. Within the above ranges, the first functional layer OR1, the second functional layer OR2 and the third functional layer OR3 may be smaller or larger than one another.

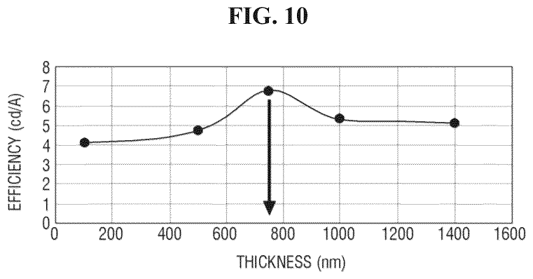

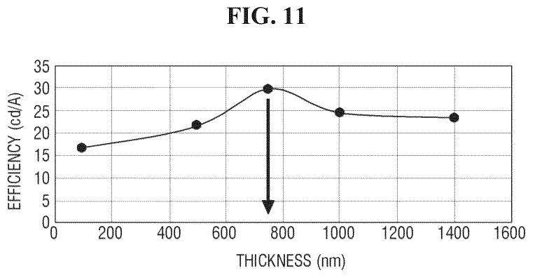

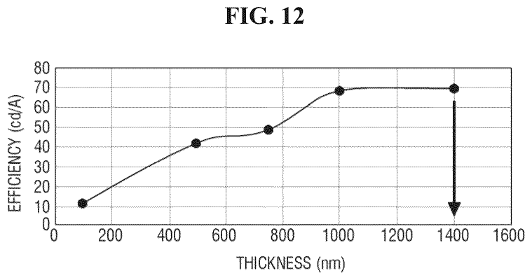

FIG. 10 is a graph showing the efficiency of the first light-emitting element. FIG. 11 is a graph showing the efficiency of the second light-emitting element. FIG. 12 is a graph showing the efficiency of the third light-emitting element. For example, FIGS. 10 to 12 show the efficiency of each of the light-emitting elements ED1, ED2 and ED3 depending on the thickness of the organic functional layer.

Referring to FIGS. 10 to 12, the first light-emitting element ED1 exhibits the maximum efficiency (e.g., cd/A) at approximately 750 nm, the second light-emitting element ED2 exhibits the maximum efficiency (e.g., cd/A) at approximately 750 nm, and the third light-emitting element ED3 exhibits the maximum efficiency (cd/A) at approximately 1,400 nm. Considering the error range, it can be seen that first to third light-emitting elements ED1, ED2 and ED3 exhibit the maximum efficiency in different ranges of thicknesses of the organic functional layer ORL.

Accordingly, in an embodiment, the first functional layer OR1, the second functional layer OR2 and the third functional layer OR3 have different thicknesses from each other, thereby increasing the efficiency, such as current efficiency, of each of the light-emitting elements ED1, ED2 and ED3.

The organic functional layer ORL described above may be applied via a solution process. For example, in an embodiment, polyacrylic acid may be mixed with a solvent and applied. According to some embodiments, the content of the polyacrylic acid may be in a range from about 0.1 to about 10 wt % with respect to the solvent.

In an embodiment, the solution process may include, for example, spin coating, inkjet printing, spraying, and slit coating. For example, according to an embodiment, by using the polyacrylic acid, which is highly soluble in the solvent, as the organic functional layer ORL, it is possible to apply it using the solution process described above. On the other hand, other polymers, such as PVA, cellulose and starch-based polymers, etc., do not dissolve in the solvent, and thus the solution process may not be possible.

The thin-film encapsulation layer TFEL may be disposed on the organic functional layer ORL and the common electrode CE (e.g., in the third direction DR3). In an embodiment, the thin-film encapsulation layer TFEL may be located commonly (e.g., commonly disposed) across the first emission area EA1, the second emission area EA2, the third emission area EA3, and the non-emission area BA. According to an embodiment of the present disclosure, the thin-film encapsulation layer TFEL may directly cover the common electrode CE and the organic functional layer ORL.

According to an embodiment of the present disclosure, the thin-film encapsulation layer TFEL may include a first inorganic encapsulation film TFE1, an organic encapsulation film TFE2 and a second inorganic encapsulation film TFE3 sequentially stacked on the common electrode CE (e.g., in the third direction DR3).

In an embodiment, each of the first inorganic encapsulation film TFE1 and the second inorganic encapsulation film TFE3 include at least one of: silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, and the like. The organic encapsulation film TFE2 may include an acrylic resin, a methacrylate-based resin, polyisoprene, a vinyl resin, an epoxy resin, an urethane resin, a cellulose resin and a perylene resin.

It is to be noted that the structure of the thin-film encapsulation layer TFEL is not necessarily limited to the above example. The stack structure of the thin-film encapsulation layer TFEL may be altered in a variety of ways.

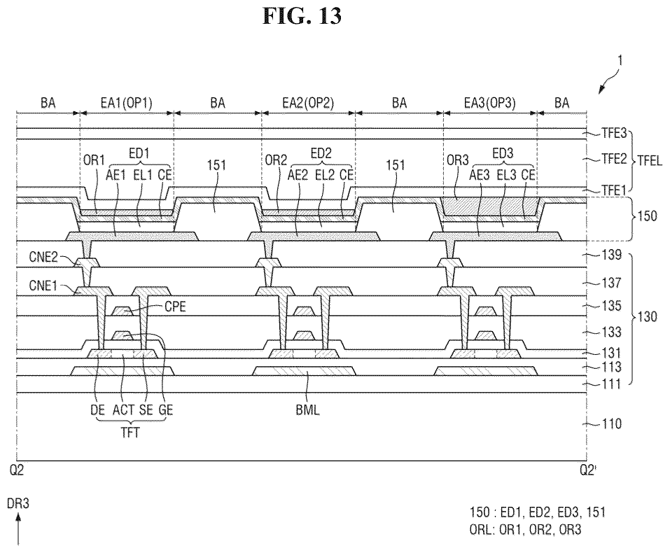

FIG. 13 is a cross-sectional view showing a display device according to an embodiment of the present disclosure.

The embodiment of FIG. 13 is different from the above-described embodiment in that the thickness (e.g., length in the third direction DR3) of a first functional layer OR1 is equal to the thickness of a second functional layer OR2, and the thickness (e.g., length in the third direction DR3) of a third functional layer OR3 is greater than the thickness of the first functional layer OR1 and the second functional layer OR2. Therefore, the following description will focus on the difference and the redundant description will be omitted for economy of description.

According to an embodiment of the present disclosure, the first functional layer OR1 and the second functional layer OR2 have the same thickness as each other, and the thickness of the third functional layer OR3 may be different from the thickness of the first functional layer OR1 and the second functional layer OR2. For example, in an embodiment the thickness TT1 of the first functional layer OR1 is equal to the thickness TT2 of the second functional layer OR2, and the thickness TT3 of the third functional layer OR3 is greater than the thickness TT1 of the first functional layer OR1 and the thickness TT2 of the second functional layer OR2.

According to embodiments of FIGS. 10 to 12 described above, the light-emitting elements exhibit the maximum efficiency when the first functional layer OR1 and the second functional layer OR2 each have a thickness of approximately 750 nm, and the light-emitting elements exhibit the maximum efficiency when the third functional layer OR3 has a thickness of approximately 1,400 nm.

Accordingly, in an embodiment as shown in FIG. 13, the thickness TT1 of the first functional layer OR1 is equal to the thickness TT2 of the second functional layer OR2, and the thickness TT3 of the third functional layer OR3 is greater than the thickness TT1 of the first functional layer OR1 and the thickness TT2 of the second functional layer OR2, so that the first to third light-emitting elements ED1, ED2 and ED3 can exhibit the maximum efficiency, such a current efficiency.

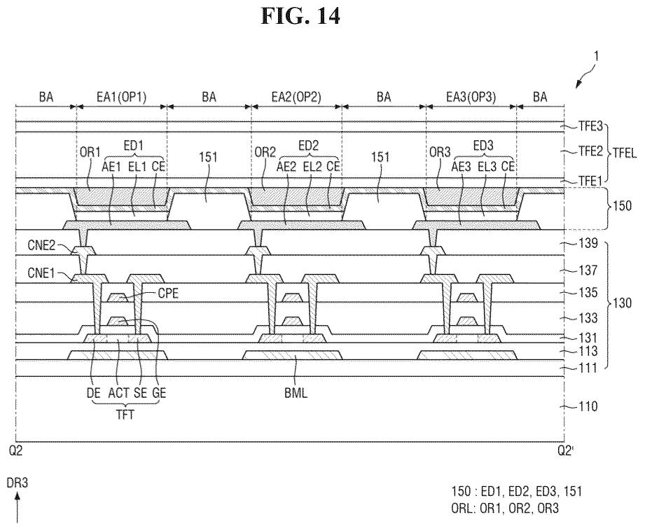

FIG. 14 is a cross-sectional view showing a display device according to an embodiment of the present disclosure.

An embodiment of FIG. 14 is different from the above-described embodiments in that the thicknesses (e.g., lengths in the third direction DR3) of a first functional layer OR1, a second functional layer OR2 and a third functional layer OR3 are all equal to each other.

According to an embodiment of the present disclosure, the first functional layer OR1, the second functional layer OR2 and the third functional layer OR3 may have the same thickness (e.g., length in the third direction DR3) to each other. For example, the thickness TT1 of the first functional layer OR1, the thickness TT2 of the second functional layer OR2, and the thickness TT3 of the third functional layer OR3 may be substantially the same. By disposing the organic functional layer ORL on each of the light-emitting elements ED1, ED2 and ED3, it is possible to remove oxygen vacancies in the electron transport layer 157 of the first to third light-emitting structures EL1, EL2 and EL3.

Accordingly, in an embodiment as shown in FIG. 14, the thickness TT1 of the first functional layer OR1, the thickness TT2 of the second functional layer OR2 and the thickness TT3 of the third functional layer OR3 are formed to be equal to one another, thereby increasing the efficiency of each of the first to third light-emitting elements ED1, ED2 and ED3, such as current efficiency.

Hereinafter, experimental examples according to the above-described embodiment will be disclosed.

### Preparation Example 1

### Comparative Example 1

Pixel electrodes of ITO were formed on a substrate, and a hole injection layer, a hole transport layer, a quantum-dot light-emitting layer, an electron transport layer and Al are sequentially formed on the ITO, to form light-emitting elements. ZnO was used for the electron transport layer.

### Example 1

Light-emitting elements were formed under the same conditions as Comparative Example 1 except that a 1,000 nm-thick organic functional layer was formed by mixing 0.5 wt % of polyacrylic acid and 10 mM of citric acid in methanol on Al.

### Example 2

Light-emitting elements were formed under the same conditions as Comparative Example 1 except that a 1,000 nm-thick organic functional layer was formed by mixing 0.25 wt % of polyacrylic acid and 10 mM of citric acid in methanol on Al.

### Experimental Example 1

The efficiency (cd/A) of each of pixels (R, G and B) of the light-emitting elements fabricated according to Comparative Example 1, Examples 1 and 2 was measured, and the results are shown in Table 1 below:

TABLE 1

| | Comparative Example 1 | | | Example 1 | | | Example 2 | | |
|---|---|---|---|---|---|---|---|---|---|
| | R | G | B | R | G | B | R | G | B |
| Efficiency | 1.4 | 8.9 | 0.25 | 3.8 | 28.4 | 1.6 | 3.1 | 21.6 | 0.9 |
| (cd/A) | | | | | | | | | |

Referring to Table 1 above, Examples 1 and 2 including an organic functional layer exhibited increased efficiency for each of the pixels (R, G and B), such as current efficiency, compared to Comparative Example 1 without an organic functional layer.

It can be seen from the above results that the display device including the organic functional layer has increased current efficiency for each of the pixels (R, G and B).

### Example 2

### Example 3

Light-emitting elements were formed under the same conditions as Comparative Example 1 except that a 750 nm-thick organic functional layer was formed by mixing 1 wt % of polyacrylic acid and 10 mM of sulfuric acid in methanol on Al.

### Example 4

Light-emitting elements were formed under the same conditions as Comparative Example 1 except that a 750 nm-thick organic functional layer was formed by mixing 1 wt % of polyacrylic acid and 10 mM of citric acid in methanol on Al.

### Experimental Example 2

The efficiency of each of pixels (R and B which are designated #1 and #2, respectively) of the light-emitting elements fabricated according to Examples 3 and 4 was measured, and the results are shown in Table 2 below:

TABLE 2

Efficiency (cd/A)

| | | |
|---|---|---|
| Pixel Type | R | B |

| | | | |
|---|---|---|---|
| Example 3 | #1 | 5.5 | 2.1 |
| | #2 | 5.6 | 2.4 |
| Example 4 | #1 | 6.1 | 3.9 |
| | #2 | 7.0 | 3.6 |

Referring to Table 2, the efficiency of the light-emitting elements of Example 4 containing citric acid was found to be higher than that of Example 3 containing sulfuric acid among the acidic substances included in the organic functional layer.

It can be seen from the results that among the acidic substances included in the organic functional layer, citric acid increases the efficiency, such as current efficiency, of the light-emitting elements more than sulfuric acid does.

### Example 3

### Comparative Example 2

Light-emitting elements were formed under the same conditions as Comparative Example 1 except that 1 wt % of polyacrylic acid and 1 wt % of methacrylic acid (MMA) were mixed in methanol on Al to form organic functional layers with thicknesses of 1,000 nm, 1,500 nm and 2,000 nm.

### Example 5

Light-emitting elements were formed under the same conditions as Comparative Example 1 except that a 1,000 nm-thick organic functional layer was formed by mixing 1 wt % of polyacrylic acid and 10 mM of citric acid in methanol on Al.

### Experimental Example 3

The white efficiency of light-emitting elements fabricated according to Comparative Example 1, Comparative Example 2 and Example 5 was measured, and the results are shown in Table 3 below: At this time, the driving current of the light-emitting elements was 5 mA/cm² and the required luminance was 146 nits.

TABLE 3

| | Thickness of Organic | Efficiency |
|---|---|---|
| | Functional Layer (nm) | (cd/A) |
| Comparative Example 1 | — | 11.1 |
| Comparative Example 2 | 1000 | 21.5 |
| | 1500 | 29.8 |
| | 2000 | 40.0 |
| Example 5 | 1000 | 57.6 |

Referring to Table 3 above, Comparative Example 2 and Example 5 including an organic functional layer exhibited increased white efficiency, compared to Comparative Example 1 without an organic functional layer. In addition, compared to Comparative Example 2 in which methacrylic acid was included in the organic functional layer, Example 5 in which citric acid was included in the organic functional layer exhibited higher white efficiency.

It can be seen from the results that a mixture of polyacrylic acid and citric acid, an acidic substance, increased the efficiency of the light-emitting elements more than a mixture of polyacrylic acid and methacrylic acid as an organic functional layer.

In concluding the detailed description, those skilled in the art will appreciate that many variations and modifications can be made to the described embodiments without substantially departing from the principles of embodiments of the present disclosure. Therefore, the described embodiments of the present disclosure are used in a generic and descriptive sense only and not for purposes of limitation.

What is claimed is:

1. A display device comprising:
a substrate;
a pixel electrode disposed on the substrate;
a bank layer covering lateral edges of the pixel electrode and including openings defining a plurality of emission areas;
a plurality of light-emitting structures, is disposed on the pixel electrode, the plurality of light-emitting structures is disposed in the plurality of emission areas, respectively;
a common electrode disposed on the plurality of light-emitting structures and the bank layer; and
an organic functional layer disposed on the common electrode and disposed in the plurality of emission areas,
wherein the organic functional layer comprises polyacrylic acid.

2. The display device of claim 1, wherein the organic functional layer further comprises an acidic substance.

3. The display device of claim 2, wherein the acidic substance comprises a carboxyl group.

4. The display device of claim 2, wherein the acidic substance comprises citric acid or sulfuric acid.

5. The display device of claim 1, wherein:
the plurality of emission areas comprises a first emission area, a second emission area and a third emission area,
wherein the organic functional layer comprises a first functional layer disposed in the first emission area, a second functional layer disposed in the second emission area, and a third functional layer disposed in the third emission area.

6. The display device of claim 5, wherein the first functional layer, the second functional layer and the third functional layer have different thicknesses from each other.

7. The display device of claim 6, wherein:
a thickness of the first functional layer is less than a thickness of the second functional layer; and
the thickness of the second functional layer is less than a thickness of the third functional layer.

8. The display device of claim 5, wherein:
a thickness of the first functional layer is equal to a thickness of the second functional layer; and
a thickness of the third functional layer is greater than the thickness of the first functional layer and the thickness of the second functional layer.

9. The display device of claim 5, wherein the first functional layer, the second functional layer and the third functional layer have a same thickness as each other.

10. The display device of claim 5, wherein a thickness of each of the first functional layer, the second functional layer and the third functional layer is in a range of about 100 nm to about 1,400 nm.

11. The display device of claim 1, wherein the organic functional layer directly contacts an upper surface of the common electrode.

12. The display device of claim 1, further comprising:
a thin-film encapsulation layer disposed on the organic functional layer,
wherein the thin-film encapsulation layer comprises a first inorganic encapsulation film, an organic encapsulation film disposed on the first inorganic encapsulation film, and a second inorganic encapsulation film disposed on the organic encapsulation film.

13. The display device of claim 1, wherein each of the light-emitting structures comprises:
a quantum-dot light-emitting layer; and
an electron transport layer disposed on the quantum-dot light-emitting layer.

14. The display device of claim 13, wherein the electron transport layer comprises metal oxide.

15. A display device comprising:
a substrate;
a light-emitting element layer disposed on the substrate and comprising a quantum-dot light-emitting layer and an electron transport layer;
a thin-film encapsulation layer disposed on the light-emitting element layer; and
an organic functional layer disposed between the light-emitting element layer and the thin-film encapsulation layer,
wherein the organic functional layer comprises polyacrylic acid and an acidic substance.

16. The display device of claim 15, wherein:
the light-emitting element layer comprises a pixel electrode disposed under the quantum-dot light-emitting layer, and a common electrode disposed on the electron transport layer,
wherein the organic functional layer directly contacts the common electrode.

17. The display device of claim 16, wherein:
the light-emitting element layer comprises a bank layer that covers lateral edges of the pixel electrode and including openings defining a plurality of emission areas; and
the plurality of emission areas comprise a first emission area, a second emission area and a third emission area, and
wherein the organic functional layer comprises a first functional layer disposed in the first emission area, a second functional layer disposed in the second emission area, and a third functional layer disposed in the third emission area.

18. The display device of claim 17, wherein:
a thickness of the first functional layer is less than a thickness of the second functional layer; and
the thickness of the second functional layer is less than a thickness of the third functional layer.

19. The display device of claim 18, wherein:
the first emission area emits first light, the first light is red;
the second emission area emits second light, the second light is green; and
the third emission area emits third light, the third light is blue.

20. The display device of claim 17, wherein a thickness of the first functional layer is equal to a thickness of the second functional layer, and a thickness of the third functional layer is greater than the thickness of the first functional layer and the thickness of the second functional layer.
